(19) United States
(12) Patent Application Publication
(10) Pub. No.: US 2007/0181062 A1
(43) Pub. Date: Aug. 9, 2007

(54) SEMICONDUCTOR DEVICE MANUFACTURING APPARATUS INCLUDING TEMPERATURE MEASURING UNIT

(76) Inventors: Il-Kyoung Kim, Seoul (KR); Kwang-Myung Lee, Hwaseong-si (KR); No-Hyun Huh, Yongin-si (KR); Wan-Goo Hwang, Yongin-si (KR); Ki-Young Yun, Yongin-si (KR)

Correspondence Address: Frank Chau, Esq.;F. CHAU & ASSOCIATES, LLC, 130 Woodbury Road, Woodbury, NY, 11797, US

(21) Appl. No.: 11/670,596

(22) Filed: Feb. 2, 2007

(30) Foreign Application Priority Data
Feb. 7, 2006 (KR) 10-2006-0011888
Apr. 10, 2006 (KR) 10-2006-0032500

(51) Int. Cl. F27D 15/02; C23C 16/00

(52) U.S. Cl. 118/715; 118/719; 432/77

(57) ABSTRACT

A semiconductor device manufacturing apparatus comprises a chamber for processing a wafer, a wafer loading unit configured to load a wafer into and out of the chamber, a heating unit coupled with a chamber wall and a temperature measuring unit located between the chamber wall and the wafer loading unit and apart from the chamber wall.

### CROSS REFERENCE TO RELATED PATENT APPLICATIONS

This application claims priority to Korean Patent Application Nos. 10-2006-0011888, filed on Feb. 7, 2006, and 10-2006-0032500, filed on Apr. 10, 2006, the disclosures of which are herein incorporated by reference in their entirety.

### BACKGROUND OF THE INVENTION

1. Technical Field

The present disclosure relates to a semiconductor device manufacturing apparatus and, more particularly, to a semiconductor device manufacturing apparatus that includes a temperature measuring unit.

2. Discussion of Related Art

In semiconductor device manufacturing apparatuses, the temperature, pressure, electric field and the flow of fluids, such as an injection gas, are controlled according to various semiconductor device manufacturing processes. Accordingly, various process conditions need to be monitored in real time. If a process parameter is not accurately controlled during manufacturing, the semiconductor device may not exhibit a normal performance.

In semiconductor device manufacturing, a high-temperature process is frequently performed. For example, an etching or deposition process that is performed in a chamber may be performed at a high temperature of several hundreds degrees. Various materials that are used in the fabrication of a semiconductor device have different transition temperatures, and precise temperature control may be required. For example, if the temperature is not precisely controlled, the reactivity of reaction gas and reaction material is not controlled, and an accurate pattern cannot be formed.

A semiconductor device manufacturing apparatus generally includes a heater for heating a wafer and the inside of a processing chamber. The heater may be provided on the wall of the chamber. When the heater heats the chamber wall, the inside of the chamber is heated, and the wafer in the chamber is heated.

A temperature measuring unit may be provided on the wall of the chamber. The temperature measuring unit may measure the temperature of the wall of the chamber to monitor the temperature of the wafer and the inside of the chamber. According to this method, the temperature of the wafer or the inside of the chamber can be measured without introducing a large error. However, a semiconductor device manufacturing apparatus may include a cooling system for cooling the wall of the chamber, for example, to improve cooling speed and efficiency within the chamber. When a temperature measuring unit senses the temperature of the chamber wall in a semiconductor device manufacturing apparatus having a cooling system, a large error may be introduced according to the temperature difference between the wafer and the chamber wall. In addition, when the temperature measuring unit is located on a chamber wall on which reaction byproducts have been deposited, the temperature of the chamber cannot be accurately measured.

To remove an oxide film, after the semiconductor wafer is introduced in the chamber gas is injected and the wafer is heated. Then, the surface of the wafer is processed. The temperature inside the chamber may reach about 200° C. or higher. When the temperature measuring unit is located at the chamber wall, since the chamber wall is cooled to 30° C., the accurate temperature of the chamber is not measured and shows 50° to 60° C. Accordingly, to accurately measure the temperature, it is necessary to wait for a period of time, for example, several minutes. If the temperature measurement is delayed, the temperature inside the chamber is not accurately measured, and the semiconductor device manufacturing process is not stably controlled. Furthermore, if the reaction byproducts are deposited on the temperature measuring unit, the temperature measurement error becomes larger.

### SUMMARY OF THE INVENTION

According to an exemplary embodiment of the present invention, a semiconductor device manufacturing apparatus comprises a chamber for processing a wafer, a wafer loading unit configured to load a wafer into and out of the; a heating unit coupled with a chamber wall; and a temperature measuring unit located between the chamber wall and the wafer loading unit and apart from the chamber wall.

The chamber may include a gas inlet port for supplying gases into the chamber, and a gas outlet port for exhausting gases out of the chamber and located to oppose the gas inlet port, and the temperature measuring unit is located closer to the gas outlet port than to the gas inlet port.

The temperature measuring unit may be a substantially cylindrical shape including an exterior of a protective tube.

A thickness of the protective tube may be 2 mm or less.

The protective tube may comprise at least one of quartz, anodized, aluminum, or a compound thereof.

The temperature measuring unit may be a thermo-couple type including electrodes formed of a nickel-chromium alloy, and at least three temperature-measuring points for measuring a temperature through contact points between a positive (+) electrode and a negative (−) electrode.

The wafer loading unit includes at least three supports, and is capable of rotating and moving in a substantially vertical direction with a plurality of wafers loaded thereon.

The heating unit may include a lamp and located to be exposed at the chamber wall.

The chamber may include a cooling system for cooling the chamber wall.

The semiconductor device manufacturing apparatus may further comprise a blocking panel disposed at the periphery of the gas outlet port to guide a gas flow.

The blocking panel may be located to be depressed from the chamber wall.

The temperature measuring unit may be located at the middle of the blocking panel to be vertically apart therefrom.

The temperature measuring unit may be located to be apart from the blocking panel and the chamber wall and on the same concentric circle as the chamber wall from a central axis of the chamber.

According to exemplary embodiment of the present invention, a chamber for manufacturing a semiconductor device, the chamber comprises a chamber wall forming an enclosed area, a gas inlet port disposed on a first surface of the chamber wall to introduce gases, a gas dispersing unit located adjacent to the gas inlet port to disperse gases introduced through the gas inlet port, a wafer loading unit for loading a wafer, a heating unit for heating inside the chamber, a temperature measuring unit located to be apart from the chamber wall between the chamber wall and the wafer loading unit to measure a temperature inside the chamber, and a gas outlet port disposed on a second surface of the chamber wall to discharge gases.

The gas inlet port and the gas outlet port may be located opposing each other; and the temperature measuring unit may be located closer to the gas outlet port than to the gas inlet port.

The heating unit may be a halogen lamp and may be located to be exposed at the chamber wall.

The chamber may further comprise a blocking panel disposed at the periphery of the gas outlet port to be depressed from the chamber wall to guide a gas flow.

The chamber may include a cooling system for cooling the chamber wall.

The temperature measuring unit may include electrodes formed of a nickel-chromium alloy, and at least three temperature-measuring points for measuring a temperature through contact points between a positive (+) electrode and a negative (−) electrode.

The temperature measuring unit may be located closer to a central axis of the chamber than the camber wall.

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is an exploded perspective view of a semiconductor device manufacturing apparatus according to an exemplary embodiment of the present invention.

FIG. 2 is a longitudinal cross-sectional view schematically showing a chamber for manufacturing a semiconductor device according to an exemplary embodiment of the present invention.

FIG. 3 is a transverse cross-sectional view schematically showing a chamber for manufacturing a semiconductor device according to an exemplary embodiment of the present invention.

FIG. 4 is a structural perspective view showing a chamber for manufacturing a semiconductor device according to an exemplary embodiment of the present invention.

FIG. 5 is an exploded perspective view schematically showing a chamber for manufacturing a semiconductor device according to an exemplary embodiment of the present invention.

FIG. 6 is a diagram illustrating a temperature measuring unit for a semiconductor device manufacturing apparatus according to an exemplary embodiment of the present invention.

FIG. 7 is a graph showing a change in temperature that is measured while a process of manufacturing a semiconductor device is performed using a semiconductor device manufacturing apparatus according to an exemplary embodiment of the present invention.

FIG. 8 is a graph showing a change in temperature that is measured while a process of manufacturing a semiconductor device is performed using a semiconductor device manufacturing apparatus according to an exemplary embodiment of the present invention.

### DESCRIPTION OF EXEMPLARY EMBODIMENTS

Exemplary embodiments of the present invention will be described in detail with reference to the accompanying drawings. Like reference numerals refer to similar or identical elements throughout the description of the figures.

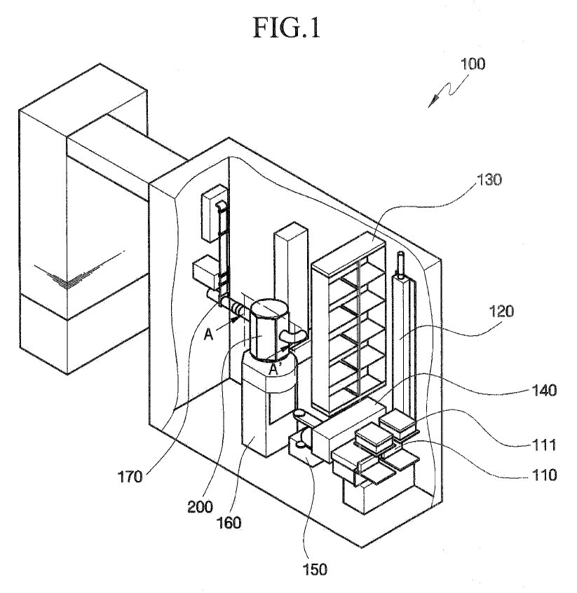

FIG. 1 is an exploded perspective view of a semiconductor device manufacturing apparatus 100 according to an exemplary embodiment of the present invention.

The semiconductor device manufacturing apparatus 100 includes a wafer cassette loading/unloading unit 110, a wafer cassette transfer unit 120, a wafer cassette stock unit 130, a worktable 140, a wafer transfer unit 150, a wafer in/out unit 160, a chamber 200 including a temperature measuring unit that may located apart from a chamber wall, and a gas pipe 170.

The wafer cassette loading/unloading unit 110 is a portion where a wafer cassette 111 is placed to be loaded into or unloaded from the semiconductor device manufacturing apparatus 100. The wafer cassette 111 may be loaded with wafers that are processed or wafers to be processed in the chamber 200.

The wafer cassette transfer unit 120 can transfer the wafer cassette 111 loaded on the wafer cassette loading/unloading unit 110 to the wafer cassette stock unit 130 and transfer the wafer cassette 111 from the wafer cassette stock unit 130 to the wafer cassette loading/unloading unit 110. The wafer cassette transfer unit 120 can transfer the wafer cassette 111 to the worktable 140, and the wafer transfer unit 150 can transfer the wafer to the wafer in/out unit 160.

The wafer in/out unit 160 may include a wafer loading unit (not shown). The wafer that is loaded in the wafer cassette 111 may be carried on the wafer loading unit by the wafer transfer unit 150. The wafer loading unit may load a plurality of wafers thereon.

After the wafer loading unit on which the wafers are loaded moves in the chamber 200, a wafer processing for manufacturing a semiconductor device may be performed. The wafer loading unit may be raised, lowered and/or rotated.

Gases may be supplied to the inside of the chamber 200 through the gas pipe 170. Various kinds of gas may be supplied according to various processes. After the wafer processing, gases may be exhausted from the chamber 200 through a gas exhaust pipe. During the wafer processing for manufacturing the semiconductor device is performed, an electric field and a magnetic field may be applied to the chamber 200.

The chamber 200 may be heated to several hundred degrees C. A heating unit (not shown) for heating the chamber may be located on a wall of the chamber 200. For example, a lamp that has a light-emitting body or a heat-emitting body, such as a tungsten filament, may be used. A cooling system for cooling the chamber 200 may be provided.

After the wafer processing for manufacturing the semiconductor device in the chamber 200 is completed, the wafer loading unit may be moved from the inside of the chamber 200 to the wafer in/out unit 160.

The wafer transfer unit 150 may transfer the wafer loaded on the wafer loading unit to the wafer cassette 111 of the worktable 140.

The wafer cassette transfer unit 120 may transfer the wafer cassette 111 of the worktable 140 to the wafer cassette carrying unit 130. The wafer cassette transfer unit 120 may transfer the wafer cassette 111 on the wafer cassette stock unit 130 to the wafer cassette loading/unloading unit 110. A next semiconductor device manufacturing process may be performed.

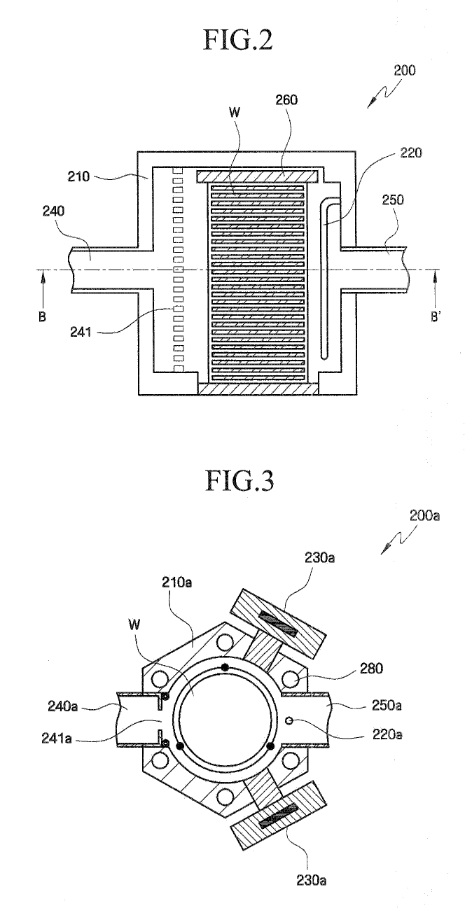

Hereafter, chamber 200 for manufacturing a semiconductor device, according to exemplary embodiments of the present invention, will be described with reference to FIGS. 2 through 5.

FIG. 2 is a longitudinal cross-sectional view schematically showing a chamber for manufacturing a semiconductor device according to an exemplary embodiment of the present invention. FIG. 2 shows the chamber 200 of the semiconductor device manufacturing apparatus of FIG. 1, taken along the line A-A′ of FIG. 1, according to an exemplary embodiment of the present invention.

Referring to FIG. 2, the chamber 200 of the semiconductor device manufacturing apparatus according to an embodiment of the invention includes a chamber wall 210, a temperature measuring unit 220 that may be located apart from the chamber wall 210, a gas in let port 240, a gas outlet port 250, and a wafer loading unit 260.

The chamber 200 may have, for example, a vertical cylindrical shape or a vertical polygonal shape.

The chamber 200 may include a gas inlet port 240 facing in one direction and a gas outlet port 250 facing in an opposing direction. The gas inlet port 240 and the gas outlet port 250 may be formed at various heights respectively. In FIG. 2, for ease of understanding, the gas inlet port 240 and the gas outlet port 250 are located at middle positions. It is to be understood that the gas inlet port 240 and the gas outlet port 250 may be located in various configurations. For example, the ports may be located in an upper portion or a lower portion respectively. The chamber 200 may include a plurality of gas inlet ports and/or gas outlet ports.

The gas inlet port 240 may inject various kinds of reaction gas into the chamber 200. Various kinds of gas or combined gases may be respectively injected according to the wafer processing to be performed in the chamber 200. Gases that are excited in a plasma state may be injected from the outside. When a process of cleaning the inside of the chamber 200, not the wafer processing, is performed, various cleaning gases may be injected.

The gas outlet port 250 may exhaust the reaction gases and the reaction by-products from the chamber 200. The gas outlet port 250 may be connected to an external pump (not shown) to exhaust gases from the chamber 200 and to vacuumize the chamber 200.

A blocking panel 270 that maintains a gas flow upon the gas exhaust may be included. The blocking panel 270 may be concave from the chamber wall 210. The blocking panel 270 may be adjacent to the temperature measuring unit 220 to be formed in a concave shape. The temperature measuring unit 220 may be located to be apart from the chamber wall 210. For example, the temperature measuring unit 220 may be located at substantially the same distance from the central axis of the chamber as the chamber wall 210. However, it is to be understood that the temperature measuring unit 220 may be positioned at various locations. For example, the temperature measuring unit 220 may be located at a distance closer to the central axis of the chamber than the chamber wall 210. As the temperature measuring unit 220 is located closer to the central axis of the chamber, the temperature of the wafer that is located at the center of the chamber may be measured with a smaller error.

The chamber 200 may include a heating unit (not shown) that heats the inside of the chamber. For example, a heating unit 230a will be described later in this disclosure with reference to FIG. 3.

The chamber wall 210, which isolates the inside of the chamber from the area outside the chamber, allows vacuumizing of the chamber. When the inside of the chamber is heated at a high temperature, the chamber wall 210 may help to preserve the temperature inside the chamber. The chamber wall 210 may be coated with a coating, such as for example, quartz or anodized aluminum. A coil or an electromagnet for applying a magnetic field to the inside of the chamber may be provided, for example, on the outside of the chamber wall 210.

The chamber 200 may include a gas dispersing unit 241 between the gas inlet port 240 and the wafer loading unit 260. For example, the gas dispersing unit 241 may be a panel having a plurality of holes. As shown in FIG. 2, the gas dispersing unit 241 may be formed over a wide area in the chamber. It is to be understood that gas dispersing unit 241 may be formed in various configurations. For example, the gas dispersing unit 241 may be formed close to the gas inlet port 240 or at an end of the gas inlet port 240.

The wafer loading unit 260 may load a plurality of wafers W. The wafer loading unit 260 may include three or four supports such that the wafers W are loaded in a horizontal direction. In each support, grooves, through which the wafers W are loaded, may be formed. A plurality, for example, several tens, of wafers W may be laminated in a horizontal state.

A multiple of the wafers to be loaded on the wafer cassette 111 may be loaded. For example, in a case where the number of wafers to be loaded on one wafer carrier is 25, the number of wafers to be loaded on the wafer loading unit 260 may be a multiple of 25, for example, 25, 50, 75, 100 or 125.

The wafer loading unit 260 may be moved in a substantially vertical direction. The wafer loading unit 260 may be vertically moved in the wafer in/out unit 160 and the chamber 200 of FIG. 1. The wafer loading unit 260 may be rotated. For example, the wafer loading unit 260 may be rotated during the wafer processing, such that the heat and reaction gases to be transmitted to the wafers W may be uniformly applied.

FIG. 3 is a transverse cross-sectional view schematically showing a chamber for manufacturing a semiconductor device according to an exemplary embodiment of the present invention. FIG. 3 shows the chamber 200 for manufacturing a semiconductor device of FIG. 2, taken along the line B-B′ of FIG. 2, according to an exemplary embodiment of the present invention.

Referring to FIG. 3, a chamber 200a for manufacturing a semiconductor device according to an exemplary embodiment of the present invention includes a chamber wall 210a, a temperature measuring unit 220a that may be located apart from the chamber wall 210a, a heating unit 230a, a gas inlet port 240a, a gas outlet port 250a, a wafer loading unit 260a, and a chamber cooling system 280.

The heating unit 230a may be inserted into the chamber wall 210a. The heating unit 230a may be inserted into the chamber wall 210a but exposed in the inside of the chamber. The heating unit 230a may be, for example, a thermoresistive type, a coil type, or the like. In an exemplary embodiment of the present invention described in connection with FIG. 3, a lamp type is used. A halogen lamp having a light-emitting body or a heat-emitting body, such as a tungsten filament, may be used. A halogen lamp may comprise a quartz tube that surrounds the tungsten filament, and gas that fills the inside of the quartz tube. The heating unit 230a may heat the chamber wall 210a to increase the temperature inside the chamber.

When the heating unit 230a is the lamp-type, the heating unit 230a may be exposed in the chamber, and the inside of the chamber and the wafers W loaded on the wafer loading unit 260a may be directly heated. The heating unit 230a may be formed in a longitudinal direction of the chamber 200a>and heating efficiency may be improved.

A chamber cooling system 280, for example, using a channel pipe or a water jacket, may be provided in the chamber wall 210a. The chamber cooling system 280 may prevent the chamber 200a from being heated unnecessarily. The chamber cooling system 280 may increase the chamber cooling efficiency and reduce the time required for cooling the chamber, and productivity may be improved. The chamber cooling system 280 may include a path or a space, such as a channel pipe or a water jacket, through which water passes in the chamber wall 210a for cooling. A pump may be provided to circulate fluids such as water or a cooling solvent. The pump may be externally located.

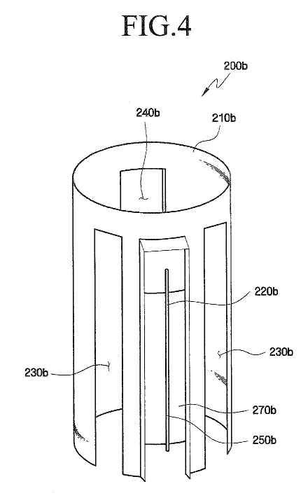

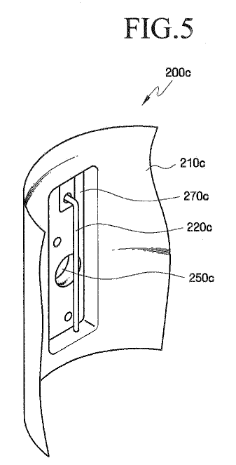

FIG. 4 is a structural perspective view showing a chamber 200b for manufacturing a semiconductor device according to an exemplary embodiment of the present invention.

Referring to FIG. 4, the chamber 200b includes a chamber wall 210b, a temperature measuring unit 220b that may be located apart from the chamber wall 210b, a heating unit 230b, a gas inlet port 240b, a gas outlet port 250b, and a blocking panel 270b.

The chamber 200b may be formed in a substantially cylindrical shape, as shown in FIG. 4. However, it is to be understood that chamber 200b may be to implemented in various configurations. For example, a polygonal shape can be used.

The chamber wall 210b may have various thicknesses. The surface of the chamber wall 210b may be coated with a coating, such as for example, quartz or anodized aluminum.

The temperature measuring unit 220b may be located to be apart from the chamber wall 210b, and may be formed lower than the height of an upper end of the blocking panel 270b. The thickness of the temperature measuring unit 220b may be less than 2 mm, and may be a cylindrical shape that is surrounded by a protective tube. The protective tube may be formed of quartz, anodized aluminum, or a compound thereof. The temperature measuring unit 220b will be described below with reference to FIG. 4.

The heating unit 230b may be a lamp. A plurality of lamps may be provided in the chamber wall 210b. The heating unit 230b may be formed long in a longitudinal direction and may be formed to be exposed in the chamber 200b. In FIG. 4, for ease of understanding, regions where the heating unit 230b may be located are shown.

The gas inlet port 240b may be located at one surface of the chamber wall 210b. In FIG. 4, for ease of understanding, only regions where the gas inlet port 240b and a gas dispersing unit may be located in the chamber 200b are shown. That is, in FIG. 4, the gas inlet port 240b and the gas dispersing unit may be located in a portion where the gas inlet port 240b is shown.

For ease of understanding, only regions where the gas outlet port 250b and the blocking panel 270b may be located are shown. The gas outlet port 250b and the blocking panel 270b will be described below with reference to FIG. 5.

FIG. 5 is an exploded perspective view schematically showing a chamber 200c for manufacturing a semiconductor device according to an exemplary embodiment of the present invention.

Referring to FIG. 5, the chamber 200c includes a chamber wall 210c, a blocking panel 270c that is formed to be depressed at one surface of the chamber wall 210c, a gas outlet port 250c, and a temperature measuring unit 220c.

The chamber 200c may have a substantially cylindrical shape, as shown in FIG. 5. It is to be understood that chamber 200c may be implemented in various configurations. For example, a polygonal shape may be used.

The chamber wall 210c is shown by a line in FIG. 5, but this is for simplification of the drawing. The chamber wall 210c may have an appropriate thickness.

The blocking panel 270c may be formed to be depressed from the chamber wall 210c. The blocking panel 270c may be formed according to the shape of the chamber 200c. The blocking panel 270c may be formed in a rectangular shape having a vertical length longer than a horizontal length as illustrated in FIG. 5.

The gas outlet port 250c may be formed in a portion of the blocking panel 270c. For example, as shown in FIG. 5, the gas outlet port 250c may be formed at the central portion. It is to be understood that the gas outlet port 250c may be formed at various positions.

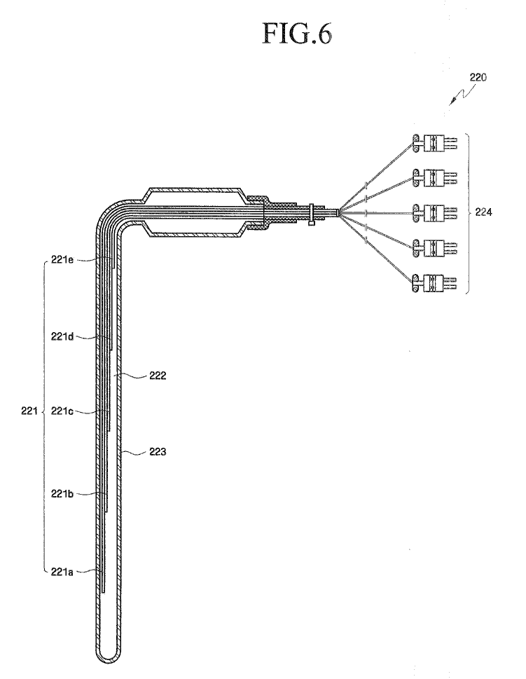

The temperature measuring unit 220c may be formed to be located apart from the chamber wall 210c, and may be adjacent to the blocking panel 270c. One end of the temperature measuring unit 220c may be formed to extend and be connected to a portion of the blocking panel 270c. The temperature measuring unit 220c may be located at a distance similar to the chamber wall 210c from the central axis of the chamber 200c. For example, the temperature measuring unit 220c may be located closer to the central axis of the chamber 200c than the chamber wall 210c. The temperature measuring unit 220c may be a long bar shape and may be located in a substantially vertical direction. FIG. 6 is a diagram illustrating a temperature measuring unit of a semiconductor device manufacturing apparatus according to an exemplary embodiment of the present invention.

Referring to FIG. 6, the temperature measuring unit 220 includes a compensation wire 221, an insulator 222, and a protective tube 223. The compensation wire 221 may be a K type that has a positive (+) electrode comprised of a nickel-chromium alloy and a negative (−) electrode comprised of nickel. The positive (+) electrode and the negative (−) electrode may contact each other, forming a measurement point where the temperature is measured. The measurement point that is formed by the positive (+) electrode and the negative (−) electrode may be located to be apart from the chamber wall 210 by a predetermined gap. Accordingly, the temperature measuring unit 220 may accurately and efficiently measure the temperature of the wafer, and an effect by the chamber wall 210 may be excluded. The measurement point of the temperature measuring unit 220 may be, for example, an exposure type, a ground type, or a non-round type. In an exemplary embodiment of the present invention, a non-ground type is used.

In the temperature measuring unit 220, a plurality of compensation wires 221 may be provided in the protective tube. At an end of each of the compensation wires, a measurement point may be formed through the contact point of the positive (+) electrode and the negative (−) electrode. The measurement point of each of the compensation wires may independently measure the temperature of the corresponding position. The measurement contact points 221a, 221b, 221c, 221d, and 221e of FIG. 6 may be provided at different lengths or heights. Accordingly, the measurement points may respectively measure the temperatures of different positions. In an exemplary embodiment of the present invention, the temperature of five places is measured It is to be understood that any suitable number of measurement points may be formed.

The temperature measuring unit may be a thermocouple type as described above, or a thermo-resister type where resistance of a measurement element is changed according to temperature.

The temperature measuring unit may be located close to the gas outlet port.

For example, the temperature measuring unit may be formed adjacent to the blocking panel that is formed in the periphery of the gas outlet port. The temperature measuring unit may be formed to be located apart from the blocking panel and in parallel with the central axis of the blocking panel. The temperature measuring unit may be formed to cross the central axis of the gas outlet port at right angles. The temperature measuring unit may be formed to be in parallel with a bisector of the gas outlet port.

The temperature measuring unit, according to exemplary embodiments of the present invention, may be configured in consideration of the following factors: shape of the temperature measuring unit, connection state of the protective tube and the internal wire of the temperature measuring unit, thickness of the temperature measuring unit, and/or the material comprising the temperature measuring unit. First, the shape of the temperature measuring unit may be considered. The temperature measuring unit may be, for example, a cylinder type or a flat panel type. The connection state of the protective tube and the internal wire of the temperature measuring unit may be considered. For example, an integrated connection or welded connection may be used. The thickness of the temperature measuring unit may be considered. When a relatively thin temperature measuring unit and a thick temperature measuring unit are compared, the thin temperature measuring unit shows a better characteristic. In an exemplary embodiment of the present invention, the temperature measuring unit is formed as thin as possible. The material of the temperature measuring unit may be considered. The same material as the chamber wall may be used. It is to be understood that various materials may be used. For example, quartz, anodized aluminum, and/or a compound thereof may be used.

Experiment and evaluation factors such as temperature proximity, time responsibility, an inter-region separation characteristic, a degree of gas flow prevention, a degree of reduction in size, ease of production, and ease of preservation may be considered. The temperature proximity refers to how the actual temperature and the measured temperature are proximate. As the actual temperature and the measured temperature are more proximate, the temperature proximity is good.

The time responsibility refers to how the measured temperature can be transmitted to a control device in a short time to be then displayed. Good time responsibility means that the temperature measured in real time is displayed in more short time and accuracy.

The inter-region separation characteristic refers to how the temperature-measuring regions are separated and the temperature of each region is independently measured. Various temperature regions may need to be controlled in the chamber. For example, in a horizontal direction, a temperature of the central axis of the wafer loading unit that is located at the center in the horizontal direction, a temperature of a peripheral outside portion, a temperature inside the chamber, and a temperature of the chamber wall may need to be controlled. In a vertical direction, a temperature of the wafer located on the upper portion of the wafer loading unit, and a temperature of the wafer located on the lower portion may need to be controlled. That is, the inter-region separation characteristic is a factor representing whether the temperature of each region may be independently measured.

The degree of gas flow prevention refers to how the temperature measuring unit does not obstruct the gas flow. Since the gas flow is precisely designed in consideration of reactivity to the wafer to be processed, a change of the gas flow may degrade a stable gas flow characteristic. The degree of reduction in size means that an occupying volume is smaller. In addition, production and preservation may be easily performed.

An experiment was conducted in which various temperature measuring units were produced, and a comparison was made on the basis of the above-described evaluation factors. The experimental results are shown in Table 1.

Table 1 is organized as a score card. Experimental results of various temperature measuring units with various evaluation factors are scored and described in Table 1.

TABLE 1

| | | Score card | | | | | | | |
|---|---|---|---|---|---|---|---|---|---|
| | | | | | Degree | | | | |
| | | | | Inter-region | of gas | Degree of | | | |
| | | Temperature | Time | separation | flow | reduction in | Ease of | Ease of | |
| | | proximity | responsibility | characteristic | prevention | size | production | preservation | |
| Item | | 7 | 6 | 5 | 4 | 3 | 2 | 1 | Total |
| Shape | Cylinder | 4 | 0 | 0 | 5 | 5 | 3 | 5 | 74 |
| | Flat panel | 5 | 0 | 0 | 3 | 3 | 4 | 2 | 66 |
| Protective | Integrated | 4 | 5 | 0 | 5 | 5 | 1 | 0 | 95 |
| tube | Welded | 3 | 4 | 0 | 3 | 3 | 5 | 0 | 76 |
| Thickness | Thin | 0 | 5 | 5 | 0 | 0 | 0 | 0 | 55 |
| | Thick | 0 | 1 | 1 | 0 | 0 | 0 | 0 | 11 |
| Material | Anodized-Al | 5 | 3 | 2 | 0 | 0 | 3 | 3 | 72 |
| | Quartz | 4 | 3 | 3 | 0 | 0 | 5 | 5 | 76 |
| | Quartz + | 3 | 4 | 3 | 0 | 0 | 4 | 4 | 72 |
| | Anodized Al | | | | | | | | |

Referring to Table 1, the numerical values of the individual evaluation factors are weighted value. Items having the evaluation score of zero may be items not considered or evaluation factors not considered in the experiment.

First, the cylinder-type protective tube and the flat plate-type protective tube of the temperature measuring unit are compared in Table 1. The temperature measuring unit having the flat panel-type protective tube has good temperature proximity and is easy to produce as compared with the temperature measuring unit having the cylinder-type protective tube. However the degree of gas flow prevention is inferior in the flat panel-type protective tube, and the reduction in size and preservation are difficult. The evaluation score in case of the cylinder type is 7×4+4×5+3×5+2×3+1×5=74. The evaluation score is 7×5+4×3+3×3+2×4+1×2=66, in case of the flat panel type.

Next, an integrated temperature measuring unit and a welded temperature measuring unit are compared. As an evaluation result by the same scoring method the integrated temperature measuring unit is 95 and the welded temperature measuring unit is 76.

A thin temperature measuring unit has superior characteristics over a thick temperature measuring unit. Specifically, two temperature measuring units were compared on the basis of 2 mm. The evaluation result may vary according to a relative difference in thickness, and thus the evaluation score is not significant.

Next, the evaluation according to the materials of the temperature measuring unit is made. The temperature measuring units comprised quartz, anodized aluminum, and a compound thereof. The temperature measuring unit formed of quartz shows slightly better characteristics as compared with the anodized aluminum.

The experimental results show that a thin temperature measuring unit in a cylinder shape, formed of quartz, and including an integrated protective tube exhibits good characteristics. In an exemplary embodiment of the present invention, a temperature measuring unit that has a cylinder shape and is formed of quartz includes an integrated protective tube, and has a thickness of less than about 2 mm.

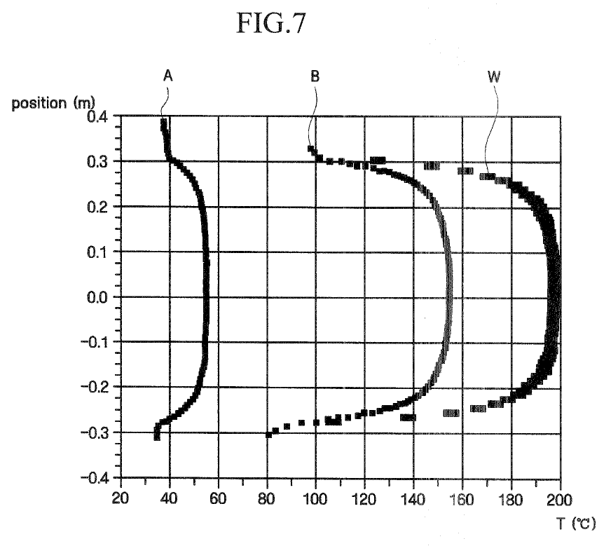

FIG. 7 is a graph showing a change in temperature that is measured while a process of manufacturing a semiconductor device is performed using a semiconductor device manufacturing apparatus according to an exemplary embodiment of the present invention.

Referring to FIG. 7, a semiconductor device manufacturing apparatus that uses a conventional temperature measuring unit shows a temperature measurement result of A, and a semiconductor device manufacturing apparatus according to an exemplary embodiment of the present invention shows a temperature measurement result of B. In FIG. 7, the X-axis represents temperature, and the Y-axis represents position in the chamber. The actual temperature of the wafer is denoted as W in FIG. 7. The semiconductor device manufacturing apparatus according to an exemplary embodiment of the present invention shows a temperature measurement result that is more proximate to the actual temperature of the wafer, as compared with a conventional semiconductor device manufacturing apparatus. In a semiconductor device manufacturing apparatus according to an exemplary embodiment of the present invention, a measurement error in the actual temperature of the wafer may be reduced, the semiconductor device manufacturing process may be more stabilized, and yield and productivity may be improved.

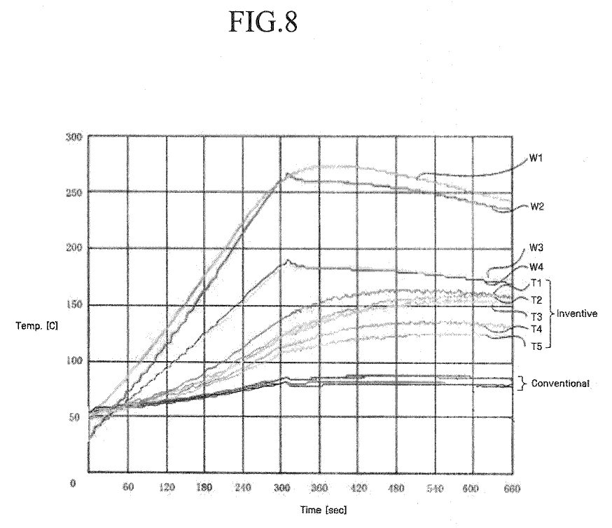

FIG. 8 is a graph showing a change in temperature that is measured while a process of manufacturing a semiconductor device is performed using a semiconductor device manufacturing apparatus according to an exemplary embodiment of the present invention.

Referring FIG. 8S the temperatures W1 to W4 of the wafer and the temperatures T1 to T5 measured by the semiconductor device manufacturing apparatus according to an exemplary embodiment of the present invention exhibit a proximate temperature measurement result in a shorter time as compared with the temperature measured by the conventional semiconductor device manufacturing apparatus. In FIG. 8, the X-axis represents time and the Y-axis represents temperature.

W1 represents the temperature of the intermediate-central portion of the wafer loading unit 260. W2 represents the temperature of the intermediate-external portion of the wafer loading unit 260. W3 represents the temperature of the lower portion-external portion of the wafer loading unit 260. W4 represents the temperature of the upper portion-external portion of the wafer loading unit 260.

The temperatures of T1 to T5 are measured for five sections of the temperature measuring unit in the semiconductor device manufacturing apparatus according to an exemplary embodiment of the present invention, in a semiconductor device manufacturing apparatus according to an exemplary embodiment of the present invention, the measured temperature is proximate to the actual temperature in a shorter time, as compared with a temperature measurement result by a conventional semiconductor device manufacturing apparatus.

The vacuum chambers for manufacturing a semiconductor device according to exemplary embodiments of the present invention may be a horizontal type or a vertical type. The vacuum chamber for manufacturing a semiconductor device according to exemplary embodiments of the present invention can be used a deposition process, a diffusion process, a heat-treatment process, an etching process, or a cleaning process.

Although exemplary embodiments of the present invention have been described in detail with reference to the accompanying drawings for the purpose of illustration, it is to be understood that the inventive processes and apparatus should not be construed as limited thereby. It will be apparent to those of ordinary skill in the art that various modifications to the foregoing exemplary embodiments may be made without departing from the scope of the invention as defined by the appended claims, with equivalents of the claims to be included therein.

What is claimed is:

1. A semiconductor device manufacturing apparatus comprising:
a chamber for processing a wafer;
a wafer loading unit configured to load a wafer into and out of the chamber;
a heating unit coupled with a chamber wall; and
a temperature measuring unit located between the chamber wall and the wafer loading unit and apart from the chamber wall.

2. The semiconductor device manufacturing apparatus of claim 1, wherein:
the chamber comprises a gas inlet port for introducing gases into the chamber, and a gas outlet port for exhausting gases out of the chamber and located to oppose the gas inlet port, and
the temperature measuring unit is located closer to the gas outlet port than to the gas inlet port.

3. The semiconductor device manufacturing apparatus of claim 1, wherein the temperature measuring unit is a substantially cylindrical shape including an exterior of a protective tube.

4. The semiconductor device manufacturing apparatus of claim 3, wherein a thickness of the protective tube is 2 mm or less.

5. The semiconductor device manufacturing apparatus of claim 3, wherein the protective tube comprises at least one of quartz, anodized aluminum, or a compound thereof.

6. The semiconductor device manufacturing apparatus of claim 1, wherein the temperature measuring unit is a thermocouple type including electrodes formed of a nickel-chromium alloy and at least three temperature-measuring points for measuring a temperature through contact points between a positive (+) electrode and a negative (−) electrode.

7. The semiconductor device manufacturing apparatus of claim 1, wherein the wafer loading unit includes at least three supports and is capable of rotating and moving in a substantially vertical direction with a plurality of wafers loaded thereon.

8. The semiconductor device manufacturing apparatus of claim 1, wherein the heating unit includes a lamp located to be exposed at the chamber wall.

9. The semiconductor device manufacturing apparatus of claim 1, wherein the chamber includes a cooling system for cooling the chamber wall.

10. The semiconductor device manufacturing apparatus of claim 1, further comprising a blocking panel disposed at the periphery of the gas outlet port to guide a gas flow.

11. The semiconductor device manufacturing apparatus of claim 10, wherein the blocking panel is located to be depressed from the chamber wall.

12. The semiconductor device manufacturing apparatus of claim 10, wherein the temperature measuring unit is located at the middle of the blocking panel to be vertically apart therefrom.

13. The semiconductor device manufacturing apparatus of claim 10, wherein the temperature measuring unit is located to be apart from the blocking panel and the chamber wall and on the same concentric circle as the chamber wall from a central axis of the chamber.

14. A chamber for manufacturing a semiconductor device, the chamber comprising:
a chamber wall forming an enclosed area;
a gas inlet port disposed on a first surface of the chamber wall to introduce gases;
a gas dispersing unit located adjacent to the gas inlet port to disperse gases introduced through the gas inlet port;
a wafer loading unit for loading a wafer;
a heating unit for heating inside the chamber;
a temperature measuring unit located to be apart from the chamber wall between the chamber wall and the wafer loading unit to measure a temperature inside the chamber; and
a gas outlet port disposed on a second surface of the chamber wall to discharge gases.

15. The chamber of claim 14, where n:
the gas inlet port and the gas outlet port are located opposing each other, and
the temperature measuring unit is located closer to the gas outlet port than to the gas inlet port.

16. The chamber of claim 14, wherein the heating unit is a halogen lamp located to be exposed at the chamber wall.

17. The chamber of claim 14, further comprising a blocking panel disposed at the periphery of the gas outlet port to be depressed from the chamber wall to guide a gas flow.

18. The chamber of claim 14, further comprising a cooling system for cooling the chamber wall.

19. The chamber of claim 14, wherein the temperature measuring unit includes electrodes formed of a nickel-chromium alloy, and at least three temperature-measuring points for measuring a temperature through contact points between a positive (+) electrode and a negative (−) electrode.

20. The chamber of claim 14, wherein the temperature measuring unit is located closer to a central axis of the chamber than the camber wall.
